(19) United States
(12) Patent Application Publication
(10) Pub. No.: US 2025/0101588 A1
(43) Pub. Date: Mar. 27, 2025

(54) SUBSTRATE PROCESSING APPARATUS

(71) Applicant: Tokyo Electron Limited, Tokyo (JP)

(72) Inventors: Masato KADOBE, Tokyo (JP); Tatsuya YAMAGUCHI, Yamanashi (JP)

(21) Appl. No.: 18/893,142

(22) Filed: Sep. 23, 2024

(30) Foreign Application Priority Data
Sep. 27, 2023 (JP) 2023-164098

(51) Int. Cl. C23C 16/455

(52) U.S. Cl. CPC C23C 16/4557; C23C 16/45561

(57) ABSTRACT

A substrate processing apparatus includes a processing container body capable of accommodating a substrate holder that holds a substrate, a pipe branching from the processing container body and extending horizontally from a sidewall of the processing container body, a temperature adjustment mechanism having a housing surrounding the pipe and configured to adjust a temperature of the pipe, and an injector arranged in the pipe.

### CROSS-REFERENCE TO RELATED APPLICATIONS

This application is based on and claims priority from Japanese Patent Application No. 2023-164098, filed on Sep. 27, 2023, with the Japan Patent Office, the disclosure of which is incorporated herein in its entirety by reference.

### TECHNICAL FIELD

The present disclosure relates to a substrate processing apparatus.

### BACKGROUND

Japanese Patent Laid-Open Publication No. 2012-169307 discloses a vertical-type film forming apparatus that includes a reaction tube, a flange unit that supports the reaction tube from the downstream side, a gas injector inserted to the inside of the reaction tube from the flange unit and extending in the height direction in the inside of the reaction tube, and an exhaust port formed on the flange unit.

### SUMMARY

According to an embodiment of the present disclosure, there is provided a substrate processing apparatus including a processing container body capable of accommodating a substrate holder that holds a substrate, a pipe branching from the processing container body and extending horizontally from a sidewall of the processing container body, a temperature adjustment mechanism having a housing surrounding the pipe and configured to adjust a temperature of the pipe, and an injector arranged in the pipe.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view illustrating an example of a substrate processing apparatus according to a first embodiment.

FIG. 2 is a horizontal cross-sectional view illustrating the example of the substrate processing apparatus according to the first embodiment.

FIG. 3 is a perspective view illustrating an example of an injector.

FIG. 4 is a cross-sectional view illustrating a structural example of the injector and a temperature adjustment mechanism.

FIG. 5 is a cross-sectional view illustrating a modification of the injector and the temperature adjustment mechanism.

FIG. 6 is a vertical cross-sectional view illustrating an example of a substrate processing apparatus according to a second embodiment.

FIG. 7 is a perspective view illustrating an example of a temperature adjustment mechanism.

FIG. 8 is a cross-sectional view illustrating a structural example of the temperature adjustment mechanism.

FIG. 9 is a horizontal cross-sectional view illustrating another example of a substrate processing apparatus.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### Substrate Processing Apparatus

### Substrate Processing Apparatus According to First Embodiment

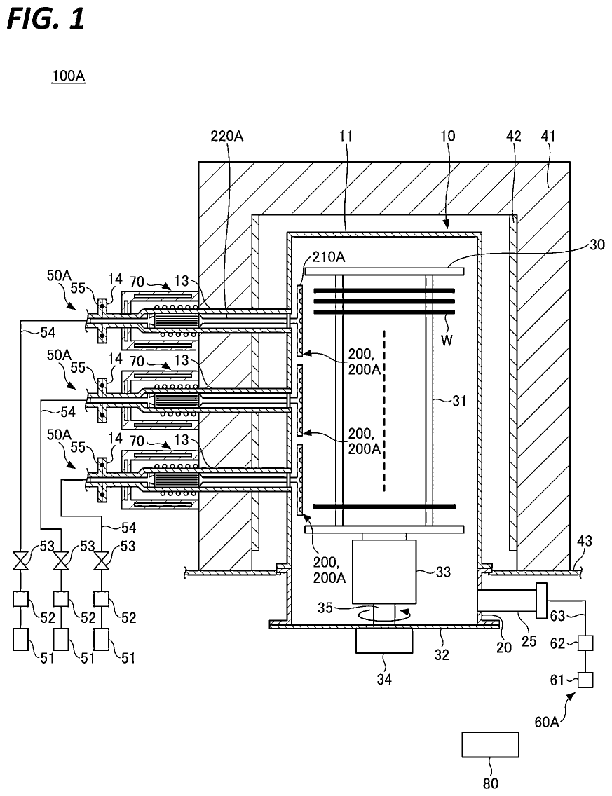

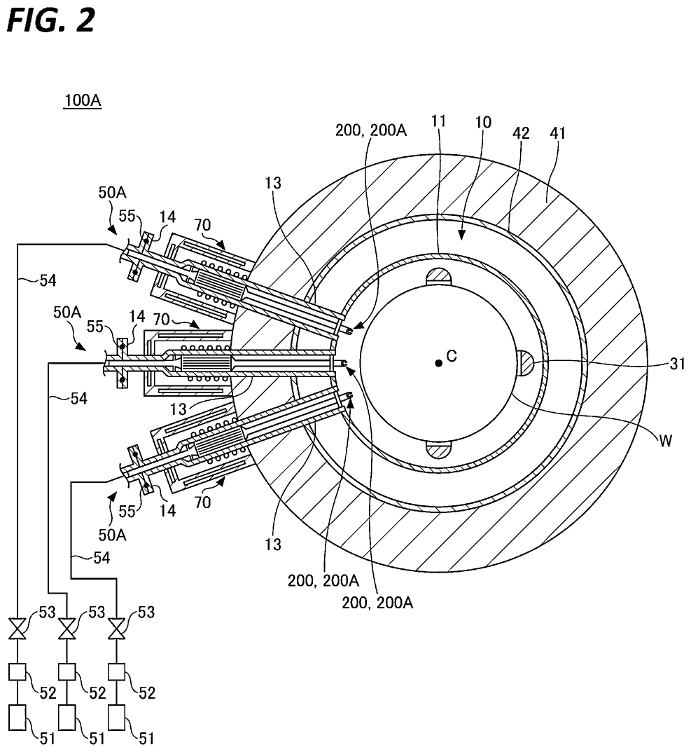

A substrate processing apparatus 100A according to a first embodiment will be described with reference to FIGS. 1 and 2. FIG. 1 is a vertical cross-sectional view illustrating an example of the substrate processing apparatus 100A according to the first embodiment. FIG. 2 is a horizontal cross-sectional view illustrating the example of the substrate processing apparatus 100A according to the first embodiment. Here, the substrate processing apparatus 100A is a film forming apparatus that forms a film on a substrate W such as a semiconductor wafer using an atomic layer deposition (ALD) method, for example, by alternately supplying two or more types of process gases.

The substrate processing apparatus 100A includes a cylindrical processing container (reaction tube) 10 with a ceiling and an open lower end. The entire processing container 10 is made of, for example, quartz.

A metallic flange 20, which is formed into a cylindrical shape, is airtightly connected to an opening at the lower end of the processing container 10 via a sealing member (not illustrated) such as an O-ring. Further, the flange 20 supports the lower end of the processing container 10.

A wafer boat (substrate holder) 30 in which a plurality of substrates W (e.g., 25 to 150 substrates) are arranged in multiple stages is inserted into the processing container 10 from below the flange 20. In this way, the plurality of substrates W are accommodated approximately horizontally with spacing along the vertical direction inside the processing container 10. The wafer boat 30 is made of, for example, quartz. The wafer boat 30 has three rods 31 (two rods are illustrated in FIG. 1), and the plurality of substrates W are supported by grooves (not illustrated) formed in the rods 31.

A metallic lid 32 is provided on the downstream side of the flange 20 to open or close a lower end opening of the flange 20. The lid 32 is configured to be freely movable up and down together with the wafer boat 30 by an elevating mechanism (not illustrated) such as a boat elevator (not illustrated). A sealing member (not illustrated) is provided between a peripheral portion of the lid 32 and the lower end of the flange 20 to maintain the airtightness inside the processing container 10.

A thermal insulator 33 made of quartz is provided between the wafer boat 30 and the lid 32. A rotation mechanism 34 rotates the wafer boat 30 and the thermal insulator 33 around the vertical axis via a rotary shaft 35. The rotary shaft 35 airtightly penetrates the lid 32 to interconnect the rotation mechanism 34 and the thermal insulator 33.

In this way, the wafer boat 30 and the lid 32 are integrally moved up and down by the elevating mechanism, and are inserted into and separated from the processing container 10. Further, the wafer boat 30 is rotated around the vertical axis by the rotation mechanism 34. It is also possible to process the substrates W without rotating the wafer boat 30.

A cylindrical thermal insulating member 41 and a heater 42 are provided around the processing container 10. The processing container 10, flange 20, thermal insulating member 41, and heater 42 are supported by a horizontally extending base plate 43. The heater 42 is arranged on an inner peripheral surface of the cylindrical thermal insulating member 41 with a ceiling and an open lower end. The heater 42 heats the processing container 10 by radiant heat and thermal convection. The heater 42 and thermal insulating member 41 control the temperature of the processing container 10 to a desired temperature. This allows the substrates W inside the processing container 10 to be heated by, e.g., radiant heat from a wall surface of the processing container 10. In other words, the heater 42 heats both the processing container 10 and the substrates W to a desired temperature.

Further, the substrate processing apparatus 100A includes a gas supplier 50A that supplies a gas into the processing container 10 and a gas exhauster 60A that exhausts the gas from the processing container 10.

Here, the processing container 10 includes a cylindrical processing container body 11 with a ceiling, a pipe 13, and a flange 14.

The processing container body 11 is a cylindrical body with a ceiling, into which the wafer boat 30 is inserted. One end at the lateral side of the processing container body 11 functions as a gas supply chamber, into which a gas is supplied. The internal space of the gas supply chamber is a part of the internal space of the processing container body 11.

The pipe 13 branches from the processing container body 11 and extends horizontally (in the radial direction of the processing container body 11) from a sidewall of the processing container body 11. The pipe 13 branches at multiple points in the height direction from the sidewall of the processing container body 11. One end of the pipe 13 communicates with the processing container body 11 (gas supply chamber), while the other end protrudes outward from the heater 42. Further, the flange 14 is provided at the other end of the pipe 13. A temperature adjustment mechanism 70 is provided between the pipe 13 and the flange 14 to face an outer side surface of the thermal insulating member 41.

An injector 200 (200A) is arranged in the processing container body 11 and the pipe 13. The gas supplier 50A is composed of the pipe 13, the injector 200 (200A), the temperature adjustment mechanism 70, a gas source 51, a flow rate adjuster 52, an on-off valve 53, and a supply path 54.

The gas source 51 supplies a gas. The flow rate adjuster 52 is, for example, a mass flow controller that adjusts the flow rate of the gas supplied from the gas source 51. The on-off valve 53 switches the supply or stoppage of the gas from the gas source 51 into the processing container 10. The supply path 54 interconnects the gas source 51 and the pipe 13, and the flow rate adjuster 52 and the on-off valve 53 are arranged in the middle of the supply path 54. The supply path 54 is connected to the pipe 13 at the outside of the heater 42. The temperature adjustment mechanism 70 adjusts the temperature of the gas supplied to the pipe 13 by heating and/or cooling the pipe 13. The heater 42 may not be necessary.

Further, the supply path 54 and the pipe 13 are airtightly connected to each other using a sealing member 55 such as an O-ring, which is made of fluorine rubber such as vinylidene fluoride rubber (FKM). The temperature adjustment mechanism 70 is provided closer to the processing container body 11 than at least the sealing member 55.

The injector 200 (200A) is arranged over the processing container body 11 and the pipe 13. The injector 200 (200A) receives the gas from the supply path 54 and discharges the supplied gas into the processing container 10.

The gas exhauster 60A includes an exhaust pipe 25 provided on a sidewall of the flange 20, a vacuum pump 61, a pressure adjuster 62, and an exhaust path 63. Thus, the gas inside the processing container 10 is exhausted out of the processing container 10 through the gas exhauster 60A. Further, the pressure inside the processing container 10 is controlled to a desired pressure by the pressure adjuster 62.

Further, the substrate processing apparatus 100A includes a controller 80. The controller 80 controls, for example, the operation of each part of the substrate processing apparatus 100. The controller 80 may be, for example, a computer, among others. Further, a computer program that executes the operation of each part of the substrate processing apparatus 100A is stored in a storage medium. The storage medium may be, for example, a flexible disk, compact disk, hard disk, flash memory, DVD, or similar device.

FIG. 2 is a horizontal cross-sectional view illustrating an example of the arrangement of the pipe 13, the injector 200 (200A), and the temperature adjustment mechanism 70 of the substrate processing apparatus 100A. A plurality of pipes 13 are connected in the circumferential direction of the processing container body 11 and the height direction of the processing container body 11 (the axial direction of the processing container body 11 and the inter-plane direction of the plurality of substrates W supported by the wafer boat 30). In the example illustrated in FIGS. 1 and 2, three pipes 13 are illustrated in the circumferential direction and two in the height direction.

Further, the temperature adjustment mechanism 70 is provided at the outer peripheral side of the pipe 13 to face the outer side surface of the thermal insulating member 41. The injector 200A is attached to the pipe 13.

The temperature adjustment mechanism 70 is provided at the outer peripheral side of the heater 42. Further, the temperature adjustment mechanism 70 is provided outside an outer peripheral surface of the thermal insulating member 41. In addition, this is not a limitation, and the temperature adjustment mechanism 70 may also be provided inside the outer peripheral surface of the thermal insulating member 41. The temperature adjustment mechanism 70 heats and/or cools the pipe 13. For example, when the pipe 13 is heated, a flow passage section 220A of the injector 200A arranged inside the pipe 13 is heated by, e.g., radiant heat from an inner peripheral surface of the pipe 13. Then, the gas flowing through the injector 200A is heated by the heated flow passage section 220A.

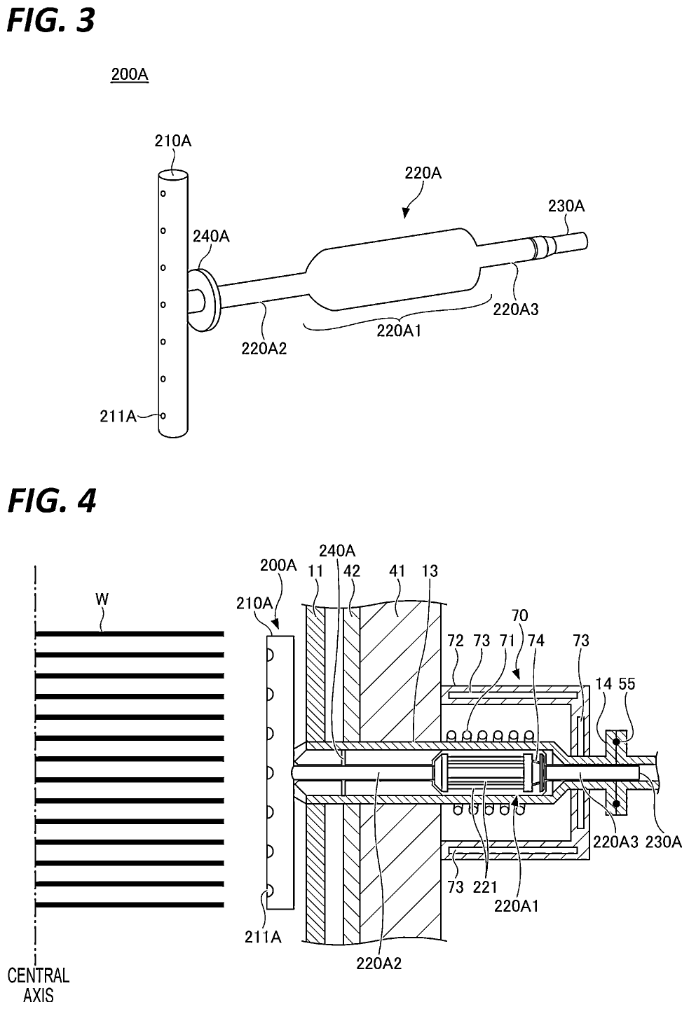

An example of the injector 200 (200A) and the temperature adjustment mechanism 70 will be described with reference to FIGS. 3 and 4. FIG. 3 is a perspective view illustrating an example of the injector 200A. FIG. 4 is a cross-sectional view illustrating a structural example of the injector 200A and the temperature adjustment mechanism 70.

As illustrated in FIG. 3, the injector 200A includes a discharge section 210A, the flow passage section 220A, a supply section 230A, and a flange section 240A. The discharge section 210A has a cylindrical shape with both closed upper and lower ends, which defines an internal space, through which the gas may flow. When the injector 200A is attached to the substrate processing apparatus 100A, the discharge section 210A is positioned inside the processing container body 11 and serves as a pipe extending in the height direction of the processing container 10.

The discharge section 210A is provided with a plurality of gas discharge holes 211A that communicate with the internal space. The plurality of gas discharge holes 211A are provided in the height direction (axial direction) of the processing container 10. In addition, the discharge section 210A has been described as having a cylindrical shape, but is not limited to this. For example, it may also take the form of a cylinder with an elliptical or polygonal cross-sectional shape.

The flow passage section 220A is a pipe having an internal space, through which the gas may flow. One end of the flow passage section 220A is connected to the discharge section 210A to enable the passage of gas, while the other end is connected to the supply section 230A to enable the passage of gas. When the injector 200A is attached to the substrate processing apparatus 100A, as illustrated in FIG. 4, the flow passage section 220A is positioned inside the pipe 13. In addition, the flow passage section 220A is illustrated as having a cylindrical shape, but is not limited to this. For example, it may also take the form of a pipe having an elliptical or polygonal cross-sectional shape.

Here, the flow passage section 220A includes second portions 220A2 and 220A3, which are straight-shaped (linear) pipes, and a first portion 220A1 between the second portions 220A2 and 220A3, the first portion 220A1 having a larger cross-sectional area than the second portions 220A2 and 220A3. The supply section 230A is connected to the supply path 54 and receives the gas from the supply path 54.

The flange section 240A is provided on an outer peripheral surface of the flow passage section 220A and is formed to be approximately equal to (slightly smaller than) the inner diameter of the pipe 13. When the injector 200A is attached to the substrate processing apparatus 100A, the flange section 240A is inserted into the pipe 13. This ensures the proper positioning of the injector 200A. Further, the flange section 240A closes the space between the inner peripheral surface of the pipe 13 and the outer peripheral surface of the flow passage section 220A as well as between the internal spaces of the processing container body 11 and the gas supply chamber. This prevents the high temperature gas in the internal space of the processing container body 11 from flowing into the space between the inner peripheral surface of the pipe 13 and the outer peripheral surface of the flow passage section 220A. In other words, this prevents the gas flowing through the injector 200 from being heated due to the high-temperature gas from the internal space of the processing container body 11. Further, this minimizes the impact on a substrate processing process caused by the communication between the space between the inner peripheral surface of the pipe 13 and the outer peripheral surface of the flow passage section 220A and the internal space of the processing container body 11.

In this way, the gas supplied from the gas source 51 flows through the supply path 54, supply section 230A, flow passage section 220A, and discharge section 210A in sequence, and is then supplied into the processing container 10 from the gas discharge holes 211A.

Details of the temperature adjustment mechanism 70 illustrated in FIG. 4 will be described. A number of fine tubes 221 are formed in the inside of the first portion 220A1 of the flow passage section 220A. A gas heating heater 71 is wound around the outer periphery of the pipe 13 corresponding to the first portion 220A1. The gas heating heater 71 is made of a metal such as tantalum. The gas heating heater 71 serves as an example of a heating mechanism.

The pipe 13 and the injector 200A are made of quartz. Through heating by the gas heating heater 71, the pipe 13 may be heated to a temperature of 1,000° C. or lower (e.g., between 800° C. and 900° C.).

A cylindrical housing 72 is arranged on the outer side surface of the thermal insulating member 41 to cover the first portion 220A1. A cylindrical sidewall of the housing 72 is formed with a thermal fluid flow path 73. One end of the cylindrical housing 72 is open and is closed by the outer side surface of the thermal insulating member 41. The other end of the cylindrical housing 72 has a bottom. The bottom has a central through-hole, through which the pipe 13 and the second portion 220A3 pass. The bottom is also formed with the thermal fluid flow path 73. The temperature of a thermal fluid flowing through the flow path 73 may be used to either cool or heat the gas flowing through the pipe 13. The thermal fluid is, for example, water, and factory water may be used. The flow path 73 inside the housing 72 is an example of a temperature adjustment mechanism that is provided in the inside of the housing 72 and adjusts the temperature of the pipe 13, and is, for example, a cooling mechanism. However, the flow path 73 may also function as a heating mechanism depending on the temperature of the thermal fluid. Further, the flow path 73 is configured to prevent the internal heat of the temperature adjustment mechanism 70 from leaking to the outside. The housing 72 is made of a metal such as stainless steel or aluminum. In addition, the flow path 73, through which the thermal fluid may flow, may be connected to a chiller. By supplying a low-temperature coolant from the chiller to the flow path 73, the pipe 13 may be cooled.

The first portion 220A1 of the flow passage section 220A and the flange section 240A have the same diameter. The second portions 220A2 and 220A3 have the same cross-sectional area. The cross-sectional area of the first portion 220A1 is larger than that of the second portions 220A2 and 220A3. The cross-sectional area of the first portion 220A1 is equal to that of the pipe 13 around the outer periphery of the second portion 220A2. The cross-sectional area of the pipe 13 around the outer periphery of the second portion 220A3 is smaller than that of the first portion 220A1 and the pipe 13 around the outer periphery of the second portion 220A2.

The plurality of fine tubes 221 are horizontally formed in the inside of the first portion 220A1 of the flow passage section 220A. The quartz forming the first portion 220A1 is heated by the gas heating heater 71 through the quartz forming the pipe 13. By bringing the gas into contact with the plurality of fine tubes 221 of the heated first portion 220A1, heat may be transferred to the gas flowing through the first portion 220A1.

Therefore, the flow passage section 220A is formed with the plurality of fine tubes 221 in the first portion 220A1 inside the pipe 13, around which the gas heating heater 71 is wound, in order to increase the surface area in contact with the gas. However, the structure of the first portion 220A1 is not limited to the fine tubes 221, as long as it has a structure that increases the contact area with the gas flowing through the first portion 220A1. For example, a spiral-shaped tube may be formed inside the first portion 220A1. The fine tubes 221 inside the first portion 220A1 may be inclined at an angle rather than being aligned horizontally.

An orifice 74 is provided at a gas inlet on an end of the first portion 220A1 toward the second portion 220A3. The orifice 74 is provided to create a pressure difference between the upstream side (toward the second portion 220A3) and the downstream side of the orifice 74. The upstream side of the orifice 74 is at approximately atmospheric pressure. The downstream side of the orifice 74 is reduced to a pressure similar to that inside the processing container body 11.

In the substrate processing apparatus 100A according to the present embodiment, due to the structure, the pressure drops most near an outlet of the discharge section 210A of the injector 200A, resulting in a decrease in gas temperature due to adiabatic expansion. Thus, even if the temperature of the gas flowing through the first portion 220A1 is adjusted by the gas heating heater 71, the gas temperature near the outlet of the injector 200A decreases, which reduces the temperature controllability of gas.

Therefore, by providing the orifice 74 on the upstream side of the first portion 220A1 and reducing the pressure inside the plurality of fine tubes 221 on the downstream side of the orifice 74 through the pressure loss caused by the orifice 74, the pressure drop at the outlet of the injector 200A is prevented. In other words, a pressure close to the pressure of the processing container body 11 is created inside the first portion 220A1 due to the pressure loss through the orifice 74, and then, the gas is heated in the first portion 220A1. Thus, it is possible to prevent a rapid decrease in the gas temperature near the outlet of the injector 200A due to adiabatic expansion, thereby enhancing the temperature controllability of the gas controlled by the gas heating heater 71.

Further, by providing the pipe 13 horizontally from the lateral side, it is possible to reduce the heating of the gas inside the injector 200 due to heat from the processing container body 11. Furthermore, the cross-sectional area of the second portion 220A2 is smaller than that of the first portion 220A1. This allows the gas supplied from the supply section 230A to increase the flow rate thereof within the second portion 220A2 and be quickly supplied to the discharge section 210A. Thus, the gas may be rapidly supplied into the processing container body 11 while maintaining the gas temperature controlled by the gas heating heater 71. Accordingly, the temperature controllability of the gas discharged from the gas discharge holes 211A is improved.

A temperature sensor (not illustrated) that detects the temperature of the flow passage section 220A may be provided in the flow passage section 220A. It is desirable to provide the temperature sensor (not illustrated) on the downstream side of the gas heating heater 71. The controller 80 may estimate the temperature of the gas supplied into the processing container 10 from the gas discharge holes 211A of the discharge section 210A based on the detected value from the temperature sensor of the flow passage section 220A.

The same type of gas may be supplied to the plurality of pipes 13 arranged in the height direction of the processing container body 11. On the other hand, different gases may be supplied to each of the pipes 13 arranged in the circumferential direction of the processing container body 11.

For example, a process of forming a film on the substrate W using an ALD process by repeating a cycle, including a step of supplying a precursor gas, which is adsorbed onto a surface of the substrate W, to the processing container 10, a step of supplying a purge gas to purge the precursor gas from the processing container 10, a step of supplying a reactant gas (e.g., an oxidizing gas or nitriding gas), which reacts with the precursor adsorbed onto the surface of the substrate W, to the processing container 10, and a step of supplying the purge gas to purge the reactant gas from the processing container 10, will be described.

For example, the precursor gas is supplied to the pipe 13 on the right side in the circumferential direction as illustrated in FIG. 2. The reactant gas is supplied to the pipe 13 on the left side in the circumferential direction. The purge gas is supplied to the central pipe 13 in the circumferential direction. Each pipe 13 is provided with the temperature adjustment mechanism 70.

With this configuration, by controlling the heater 42 and the temperature adjustment mechanism 70 respectively, the temperature of the processing container body 11 heated by the heater 42, the temperature of the precursor gas supplied from the injector 200A to the processing container 10, the temperature of the reactant gas supplied from the injector 200A to the processing container 10, and the temperature of the purge gas supplied from the injector 200A may be varied. In other words, it is possible to control the temperature of the gas supplied to the processing container 10 for each type of gas.

Thus, for example, the precursor gas may be supplied to the processing container 10 at a temperature suitable for adsorbing onto the surface of the substrate W. Further, the reactant gas may be supplied to the processing container 10 at a temperature suitable for reacting with the precursor gas adsorbed onto the surface of the substrate W. Further, the purge gas may be supplied, for example, in order to cool the substrate W.

Further, by providing the temperature adjustment mechanism 70 on the downstream side of the sealing member 55 and constructing it to heat the gas on the downstream side of the sealing member 55, the gas may be brought to a desired temperature in advance, independent of the temperature of the processing container body 11, and then supplied to the processing container body 11 while protecting the sealing member 55.

Since the main heater 42 is controlled to a uniform temperature, using only the heater 42 for temperature control may result in the film thickness on the upper substrates W in the wafer boat 30 being greater than that on the lower substrates W during processing. In this case, one example approach is to increase the temperature of the gas supplied to the processing container 10 from the lower injector 200A and to decrease the temperature of the gas supplied to the processing container 10 from the upper injector 200A. This allows the film thickness on the upper and lower substrates W in the wafer boat 30 to be equalized. However, the temperature control of each injector 200A arranged in the height direction is not limited to this method.

Further, by flowing a cooling medium as an example of the thermal fluid through the flow path 73, the injector 200A may be cooled in the first portion 220A1 to supply the gas to the processing container 10 in a less active state. For example, when dealing with gases that decompose easily at high temperatures, the cooling effect of the cooling medium may prevent the gas from excessively decomposing before it is supplied to the processing container 10. A gas such as O₃ gas is an example of one that would benefit from this cooling to reduce activation thereof. Conversely, by using the gas heating heater 71 to heat the injector 200A in the first portion 220A1, the gas may be fully activated before being supplied to the processing container 10. Examples of gases that need to be activated by heating may include ammonia (NH₃) and hydrogen (H₂) gases.

Further, for a single gas, the flow rate and/or temperature of the gas may be controlled in the height direction by supplying the gas into the processing container 10 from the plurality of pipes 13. In other words, the gas flow rate and/or the gas temperature may be controlled for each height direction region (zone).

Further, the substrate processing apparatus 100A is configured to allow the injector 200 (200A) to be replaceable (detachable). This enables the shape of the gas supplier 50A to be modified by exchanging the injector 200 with one that has a different number, size, or arrangement of the gas discharge holes 211A. The injector 200 (200A) may also have an L-shaped form. The discharge section 210A of the injector 200 (200A) may be erected upright.

With the substrate processing apparatus 100A according to the first embodiment, the gas supplied to the processing container 10 may be adjusted.

In other words, a plurality of regions (zones) are formed in the height direction of the processing container 10. Then, each region corresponds to the injector 200. With the substrate processing apparatus 100A according to the first embodiment, as illustrated in FIG. 1, the flow rate of the gas supplied to each pipe 13 in the height direction may be individually controlled by the flow rate adjuster 52. This allows for the control of the flow rate of gas supplied to each of the plurality of regions. Further, the injector 200 is detachable. Exchanging the injector 200 with another injector having a different shape or configuration may also control the flow rate of gas supplied to each region.

Further, with the substrate processing apparatus 100A according to the first embodiment, by individually controlling the gas heating heater 71 corresponding to each pipe 13 in the height direction, the temperature of the gas being supplied may be individually controlled. This allows for the control of the temperature of gas supplied to each of the plurality of regions.

With the substrate processing apparatus 100A according to the first embodiment, both the flow rate and temperature of the gas being supplied may be controlled based on the type of gas for each region.

Thus, the gas supplied into the processing container 10 from the gas discharge holes 211A passes between the substrates W supported by the wafer boat 30 and is exhausted out of the processing container 10 through the exhaust pipe 25. This may improve the uniformity of the flow rate and temperature of the gas supplied via side flow, thereby enhancing the uniformity of substrate processing.

### Modification of Injector and Temperature Adjustment Mechanism

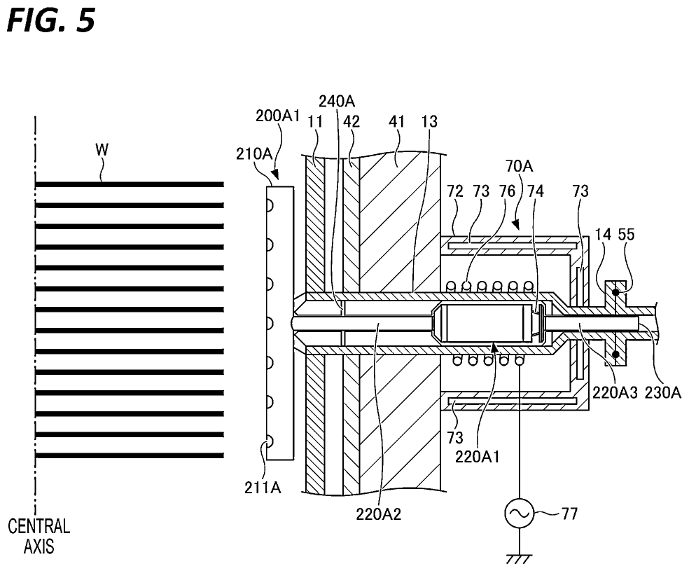

Referring to FIG. 5, a modification of an injector 200 (200A1) and a temperature adjustment mechanism 70A will be described. FIG. 5 is a cross-sectional view illustrating the modification of the injector 200 (200A1) and the temperature adjustment mechanism 70A.

The external appearance of the injector 200 (200A1) illustrated in FIG. 5 is the same as that of the injector 200 (200A) illustrated in FIG. 3, and therefore, the description thereof will be omitted.

A basic configuration of the injector 200 (200A1) illustrated in FIG. 5 is identical to that of the injector 200 (200A) illustrated in FIG. 4. In the injector 200 (200A1) illustrated in FIG. 5, the inside of the first portion 220A1 of the flow passage section 220A serves as a plasma generation space.

Further, the temperature adjustment mechanism 70A includes an induction coil 76 wound around the periphery of the pipe 13 according to the first portion 220A1. Radio-frequency power is supplied to the induction coil 76 from a radio-frequency power supply 77. Thus, the gas flowing through the flow passage section 220A forms a plasma by the radio-frequency power while passing through the first portion 220A1. This allows for the generation of plasma from the gas supplied into the first portion 220A1.

With the injector 200 (200A1) and the temperature adjustment mechanism 70A according to this modification, the same effects as those of the injector 200 (200A) and the temperature adjustment mechanism 70 illustrated in FIG. 4 may be obtained. Furthermore, in this modification, the gas may be supplied to the processing container body 11 in a more decomposed state by increasing the activity of the gas through plasma generation in the first portion 220A1.

### Substrate Processing Apparatus 100B According to Second Embodiment

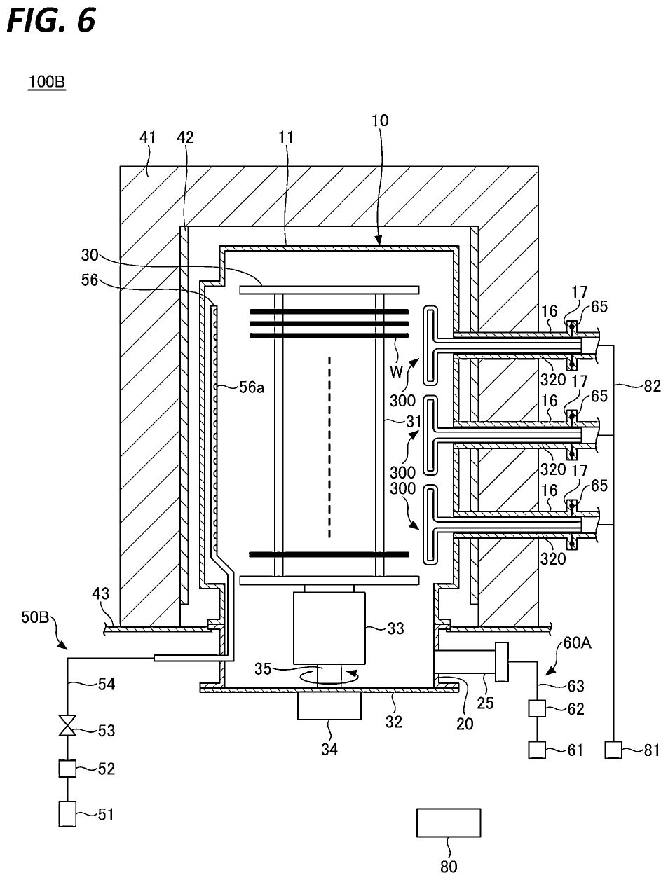

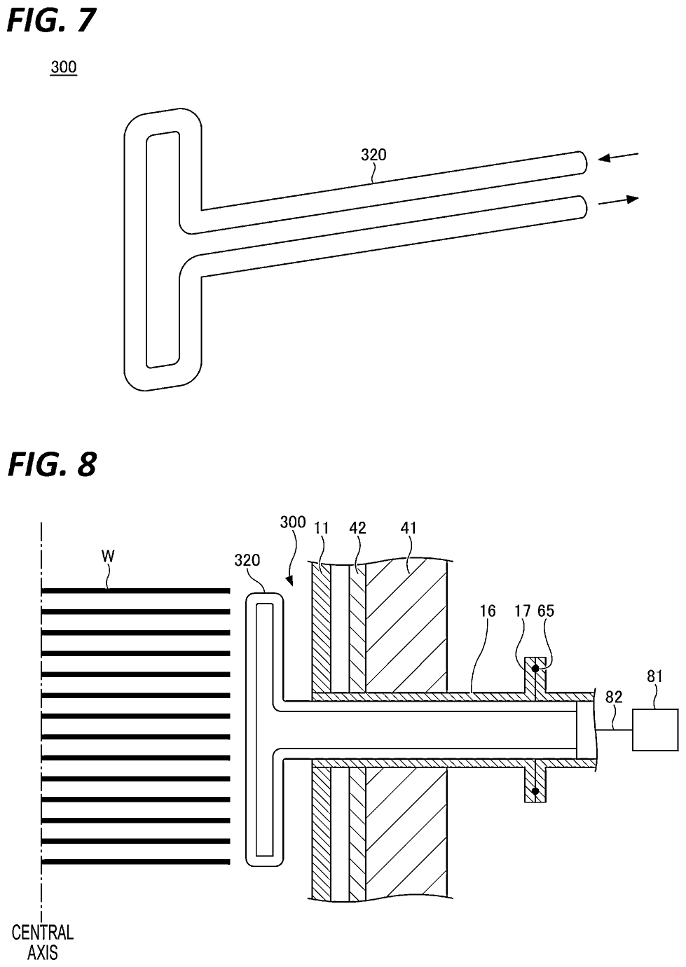

A substrate processing apparatus 100B according to a second embodiment will be described with reference to FIGS. 6 to 8. FIG. 6 is a vertical cross-sectional view illustrating an example of the substrate processing apparatus 100B according to the second embodiment. FIG. 7 is a perspective view illustrating an example of a temperature adjustment mechanism 300. FIG. 8 is a cross-sectional view illustrating a structural example of the temperature adjustment mechanism 300. Here, the substrate processing apparatus 100B is a film forming apparatus that forms a film on the substrate W using an ALD method, for example, by alternately supplying two or more types of process gases.

The substrate processing apparatus 100B includes the cylindrical processing container (reaction tube) 10 with a ceiling and an open lower end. The entire processing container 10 is made of, for example, quartz.

The metallic flange 20, which is formed into a cylindrical shape, is airtightly connected to an opening at the lower end of the processing container 10 via a sealing member (not illustrated) such as an O-ring. Further, the flange 20 supports the lower end of the processing container 10.

The wafer boat (substrate holder) 30 in which the plurality of substrates W (e.g., 25 to 150 substrates) are arranged in multiple stages is inserted into the processing container 10 from below the flange 20. In this way, the plurality of substrates W are accommodated approximately horizontally with spacing along the vertical direction inside the processing container 10. The wafer boat 30 is made of, for example, quartz. The wafer boat 30 has three rods 31 (two rods are illustrated in FIG. 7), and the plurality of substrates W are supported by grooves (not illustrated) formed in the rods 31.

The metallic lid 32 is provided on the downstream side of the flange 20 to open or close an opening at the lower end of the flange 20. This lid 32 is configured to be freely movable up and down together with the wafer boat 30 by an elevating mechanism (not illustrated) such as a boat elevator (not illustrated). A sealing member (not illustrated) is provided between the periphery of the lid 32 and the lower end of the flange 20 to maintain the airtightness inside the processing container 10.

The thermal insulator 33 made of quartz is provided between the wafer boat 30 and the lid 32. The rotation mechanism 34 rotates the wafer boat 30 and the thermal insulator 33 around the vertical axis via the rotary shaft 35. The rotary shaft 35 airtightly penetrates the lid 32 to interconnect the rotation mechanism 34 and the thermal insulator 33.

In this way, the wafer boat 30 and the lid 32 are integrally moved up and down by the elevating mechanism, and are inserted into and separated from the processing container 10. Further, the wafer boat 30 is rotated around the vertical axis by the rotation mechanism 34. It is also possible to process the substrates W without rotating the wafer boat 30.

The cylindrical thermal insulating member 41 and the heater 42 are provided around the processing container 10. The processing container 10, flange 20, insulating member 41, and heater 42 are supported by the horizontally extending base plate 43. The heater 42 includes the cylindrical thermal insulating member 41 with a ceiling and an open lower end and the heater 42 arranged on the inner peripheral surface of the thermal insulating member 41. The heater 42 heats the processing container 10 by radiant heat from the heater 42 and thermal convection. The heater 42 controls the temperature of the processing container 10 to reach a desired temperature. Thus, the substrates W inside the processing container 10 are heated by, e.g., radiant heat from a wall surface of the processing container 10. In other words, the heater 42 heats the processing container 10 and the substrates W to a desired temperature.

Further, the substrate processing apparatus 100B includes a gas supplier 50B that supplies a gas into the processing container 10 and a gas exhauster 60B that exhausts the gas from the processing container 10.

The gas supplier 50B includes the gas source 51, the flow rate adjuster 52, the on-off valve 53, the supply path 54, and a gas supply pipe 56.

The gas source 51 supplies a gas. The flow rate adjuster 52 is, for example, a mass flow controller that adjusts the flow rate of the gas supplied from the gas source 51. The on-off valve 53 switches the supply or stoppage of the gas from the gas source 51 into the processing container 10. The supply path 54 interconnects the gas source 51 and the gas supply pipe 56, and the flow rate adjuster 52 and the on-off valve 53 are arranged in the middle of the supply path 54. The gas supply pipe 56 is inserted into the processing container 10 from the flange 20 and is placed inside the gas supply chamber. The gas supply pipe 56 is formed with a plurality of discharge portions 56a in the height direction.

The gas exhauster 60B includes the exhaust pipe 25 provided on a sidewall of the flange 20, the vacuum pump 61, the pressure adjuster 62, and the exhaust path 63. Thus, the gas inside the processing container 10 is exhausted out of the processing container 10 through the gas exhauster 60B. Further, the pressure inside the processing container 10 is controlled to a desired pressure by the pressure adjuster 62.

Further, the substrate processing apparatus 100B includes the controller 80. The controller 80 controls, for example, the operation of each part of the substrate processing apparatus 100B. The controller 80 may be, for example, a computer, among others. Further, a computer program that executes the operation of each part of the substrate processing apparatus 100B is stored in a storage medium. The storage medium may be, for example, a flexible disk, compact disk, hard disk, flash memory, DVD, or similar device.

Here, the processing container 10 includes the cylindrical processing container body 11 with a ceiling, a pipe 16, a flange 17, and a temperature adjustment pipe 320.

The processing container body 11 is a cylindrical body with a ceiling, into which the wafer boat 30 is inserted. One end at the lateral side of the processing container body 11 functions as a gas supply chamber, into which the gas is supplied. The internal space of the gas supply chamber is a part of the internal space of the processing container body 11.

The pipe 16 branches from the processing container body 11 and extends horizontally (in the radial direction of the processing container body 11) from a sidewall of the processing container body 11. The pipe 16 branches at multiple points in the height direction from the sidewall of the processing container body 11. The pipe 16 has one end that communicates with the processing container body 11, extends horizontally (in the radial direction of the processing container body 11), and penetrates the lateral side of the heater 42, and the other end protrudes outward from the heater 42. The flange 17 is provided at the other end of the pipe 16. A supply path 82 is airtightly connected to the pipe 16 using a sealing member 65 such as an O-ring, which is made of fluorine rubber such as vinylidene fluoride rubber (FKM).

The temperature adjustment mechanism 300 is arranged in the processing container body 11 and the pipe 16. As illustrated in FIGS. 7 and 8, the temperature adjustment mechanism 300 includes the temperature adjustment pipe 320. The temperature adjustment pipe 320 is connected to a chiller unit 81 through the supply path 82. The temperature adjustment pipe 320 is made of quartz.

The temperature adjustment pipe 320 is an annular member, through which a thermal fluid circulates. Alternatively, the temperature adjustment pipe 320 may be a rod-shaped member, and a circulation flow path may be formed on a surface of the temperature adjustment pipe 320. The temperature adjustment mechanism 300 circulates the thermal fluid, the temperature of which has been adjusted by the chiller unit 81, to the temperature adjustment pipe 320 through the supply path 82. As illustrated in FIG. 8, the temperature adjustment pipe 320 is arranged such that two pipes are in contact with an inner surface of the pipe 16, and extends in the height direction from the pipe 16 to the processing container body 11 to have a T-shaped cross section near the substrates W inside the processing container body 11.

An inert gas such as an N₂ gas is circulated as the thermal fluid through the temperature adjustment pipe 320. The temperature adjustment pipe 320 circulates the supplied thermal fluid such as N₂ gas near the substrates W and returns it to the chiller unit 81. By circulating the thermal fluid such as N₂ gas near the substrates W in this manner, the substrate in-plane edge temperature may be rapidly heated or cooled depending on the temperature of the thermal fluid.

With the temperature adjustment mechanism 300 according to the second embodiment, the in-plane edge temperature of the substrate W may be locally controlled by circulating the heated or cooled thermal fluid through the temperature adjustment pipe 320. This allows for the control of the temperatures in the edge and center in the plane of the substrate W.

Further, by circulating the cooled thermal fluid through the temperature adjustment pipe 320, the temperature of the processing container body 11 may be rapidly lowered. This cooling effect by the temperature adjustment pipe 320 is particularly effective in low temperature processes inside the processing container body 11. By circulating the thermal fluid that has been controlled to a predetermined temperature through the temperature adjustment pipe 320, it is possible to quickly achieve uniform temperature in the plane of the substrate, or to adjust the temperature difference between the center and edge of the substrate W to conditions favorable for film formation. This serves as a knob for adjusting the in-plane uniformity of the substrate W.

### Others

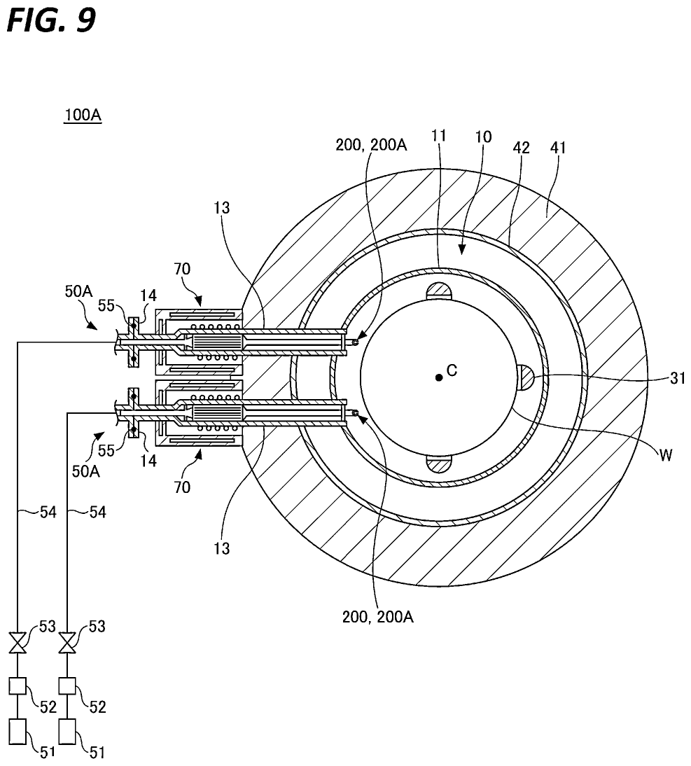

The plurality of pipes 13 and 16 may be provided in the circumferential direction (horizontal direction) of the processing container body 11 and/or in the axial direction (vertical direction) of the processing container body 11. As illustrated in FIG. 2, the plurality of pipes 13 and 16 may be arranged radially toward the central axis C of the processing container body 11. As illustrated in FIG. 9, the plurality of pipes 13 and 16 may be arranged parallel to each other without facing the central axis C of the processing container body 11. The pipes 13 and 16 may also be arranged in a single layer.

The injector 200A and the temperature adjustment mechanism 70 of the first embodiment (see FIG. 4), the injector 200A1 and the temperature adjustment mechanism 70A of the modification (see FIG. 5), and the temperature adjustment mechanism 300 of the second embodiment (see FIG. 8) may be combined in two or more and applied to a substrate processing apparatus.

When combining the temperature adjustment mechanism 300 of the second embodiment with at least one of the injector 200A and the temperature adjustment mechanism 70 of the first embodiment, or the injector 200A1 and the temperature adjustment mechanism 70A of the modification, it is preferable to combine them in the circumferential direction of the processing container body 11.

According to one aspect, it is possible to provide a substrate processing apparatus capable of adjusting a gas supplied into a processing container.

From the foregoing content, it will be appreciated that various embodiments of the present disclosure have been described herein for purposes of illustration, and that various modifications can be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container configured to accommodate a substrate holder that holds a substrate;
a pipe branching from the processing container and extending horizontally from a sidewall of the processing container;
a temperature controller including a housing surrounding the pipe and configured to adjust a temperature of the pipe; and
an injector arranged in the pipe.

2. The substrate processing apparatus according to claim 1, wherein the temperature controller includes a heater and a cooler provided in an inside of the housing.

3. The substrate processing apparatus according to claim 2, wherein the heater is wound around an outer periphery of the pipe inside the housing.

4. The substrate processing apparatus according to claim 2, wherein the cooler is a flow path formed in the housing to flow a thermal fluid therethrough.

5. The substrate processing apparatus according to claim 1, wherein the injector is detachably arranged in the pipe.

6. The substrate processing apparatus according to claim 2, wherein the injector includes:
a discharge section having a plurality of gas discharge holes; and
a flow passage section that communicates with the discharge section and is arranged inside the pipe, and
wherein the flow passage section includes a first portion where the heater is provided, the first portion having a larger cross-sectional area than a remaining portion.

7. The substrate processing apparatus according to claim 6, wherein the first portion of the flow passage section includes a plurality of fine tubes.

8. The substrate processing apparatus according to claim 6, wherein the heater is an induction coil that supplies radio-frequency power, and
wherein an inside of the first portion of the flow passage section is a plasma generation space that generates a plasma from a gas.

9. The substrate processing apparatus according to claim 6, wherein an orifice is provided at a gas inlet to the first portion of the flow passage section.

10. A substrate processing apparatus comprising:
a processing container configured to accommodate a substrate holder that holds a substrate;
a pipe branching from the processing container body and extending horizontally from a sidewall of the processing container; and
a temperature controller detachably arranged in the pipe.

11. The substrate processing apparatus according to claim 1, further comprising a seal configured to airtightly seal a connection between a supply path that supplies a gas and the pipe,
wherein the temperature controller is provided closer to the processing container than at least the seal.

12. The substrate processing apparatus according to claim 1, wherein the pipe includes a plurality of pipes provided in an axial direction of the processing container.

13. The substrate processing apparatus according to claim 1, wherein the pipe includes a plurality of pipes provided in a circumferential direction of the processing container.

14. The substrate processing apparatus according to claim 1, wherein a plurality of pipes is provided in a circumferential direction and an axial direction of the processing container, and
the plurality of pipes are arranged radially toward a central axis of the processing container.

15. The substrate processing apparatus according to claim 1, wherein a plurality of pipes is provided in a circumferential direction and an axial direction of the processing container, and
the plurality of pipes are arranged parallel to each other.
